(19) United States
(12) Patent Application Publication
(10) Pub. No.: US 2026/0052685 A1
(43) Pub. Date: Feb. 19, 2026

(54) FLASH MEMORY AND MANUFACTURING METHOD THEREOF

(71) Applicant: Winbond Electronics Corp., Taichung City (TW)

(72) Inventors: Ting-Wei Wu, Taichung City (TW); Hsiu-Han Liao, Hsiuchu (TW)

(73) Assignee: Winbond Electronics Corp., Taichung City (TW)

(21) Appl. No.: 19/298,204

(22) Filed: Aug. 13, 2025

(30) Foreign Application Priority Data
Aug. 13, 2024 (TW) 113130372

(51) Int. Cl. H10B 41/30

(52) U.S. Cl. CPC H10B 41/30

(57) ABSTRACT

A manufacturing method of a flash memory includes the following. A plurality of isolation structures are formed in a substrate. The plurality of isolation structures protrude from a top surface of the substrate. A tunneling dielectric layer is formed. The tunneling dielectric layer includes a plurality of corner oxide layers and an oxide layer. The plurality of corner oxide layers are located on the substrate at a plurality of corners between two adjacent isolation structures. A center of curvature of an upper surface of each of the corner oxide layers is located on a side of the upper surface away from the substrate. The oxide layer is located on the substrate between two adjacent isolation structures. The plurality of corner oxide layers are located between the oxide layer and the substrate.

### CROSS-REFERENCE TO RELATED APPLICATION

This application claims the priority benefit of Taiwan application serial no. 113130372, filed on Aug. 13, 2024. The entirety of the above-mentioned patent application is hereby incorporated by reference herein and made a part of this specification.

### BACKGROUND

### Technical Field

The disclosure relates to a flash memory and a manufacturing method thereof, and in particular, relates to a tunneling oxide layer of a flash memory and a manufacturing method thereof.

### Description of Related Art

As the flash memory process is miniaturized, generally, shallow trench isolation (STI) technology is used to form an isolation structure in the substrate to separate adjacent active areas. However, when a tunneling oxide layer is subsequently formed on the active area in the substrate, thinning at the corners of the tunneling oxide layer frequently occurs. As a result, thinning of the tunneling oxide layer at the corners increases edge field effects and collapse, reducing data retention capability and reliability of the flash memory.

Further, in some conventional flash memory manufacturing processes, after the pad oxide layer is removed and before the tunneling oxide layer are formed, an excessive dry etching is used to modify the shape of the isolation structure and to expose the substrate. The substrate may be damaged and the reliability of the flash memory may thus be affected.

### SUMMARY

The disclosure provides a flash memory and a manufacturing method thereof that address corner thinning in the tunneling dielectric layer.

The disclosure provides a manufacturing method of a flash memory, and the method includes the following steps. A plurality of isolation structures are formed in a substrate. The plurality of isolation structures protrude from a top surface of the substrate. A tunneling dielectric layer is formed. The tunneling dielectric layer includes a plurality of corner oxide layers and an oxide layer. The plurality of corner oxide layers are located on the substrate at a plurality of corners between two adjacent isolation structures. A center of curvature of an upper surface of each of the corner oxide layers is located on a side of the upper surface away from the substrate. The oxide layer is located on the substrate between two adjacent isolation structures. The plurality of corner oxide layers are located between the oxide layer and the substrate.

The disclosure further provides a flash memory including a substrate, a plurality of isolation structures, and a tunneling dielectric layer. The plurality of isolation structures are located in the substrate and protrude from a top surface of the substrate. The tunneling dielectric layer includes a plurality of corner oxide layers and an oxide layer. The plurality of corner oxide layers are located on the substrate at a plurality of corners between two adjacent isolation structures. A center of curvature of an upper surface of each of the corner oxide layers is located on a side of the upper surface away from the substrate. The oxide layer located on the substrate between two adjacent isolation structures. The plurality of corner oxide layers are located between the oxide layer and the substrate.

Based on the above, in the flash memory and the manufacturing method provided by the disclosure, the tunneling dielectric layer includes corner oxide layers and an oxide layer. Since the plurality of corner oxide layers between two adjacent isolation structures are located between the oxide layer and the substrate, corner thinning in the tunneling dielectric layer on the active area is prevented. In this way, data retention capability and reliability of the flash memory are improved.

To make the aforementioned more comprehensible, several embodiments accompanied with drawings are described in detail as follows.

### BRIEF DESCRIPTION OF THE DRAWINGS

FIG. 1A to FIG. 1G are cross-sectional views of a manufacturing process of a flash memory according to some embodiments of the disclosure.

FIG. 2 is an enlarged view of a region R1 in FIG. 1G.

### DESCRIPTION OF THE EMBODIMENTS

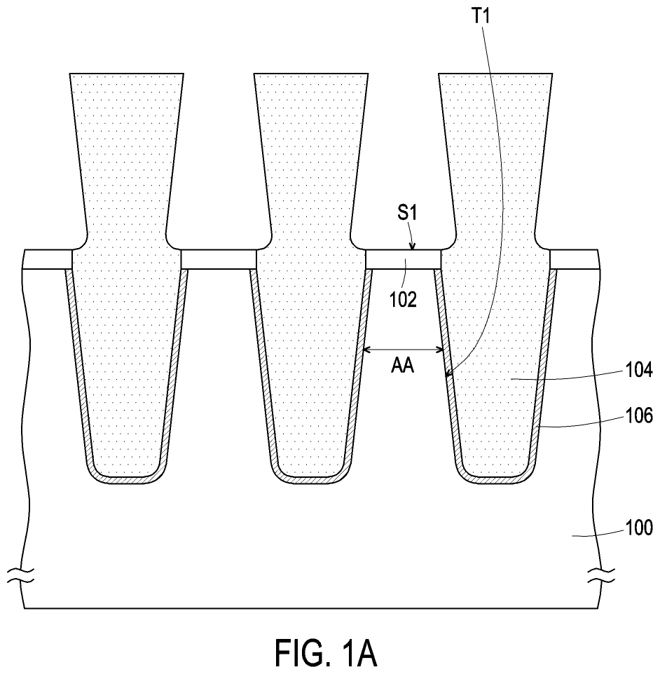

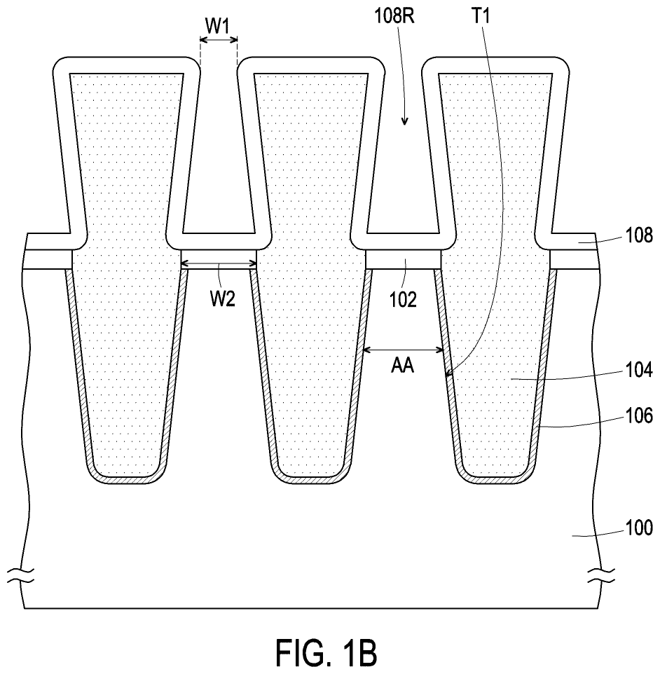

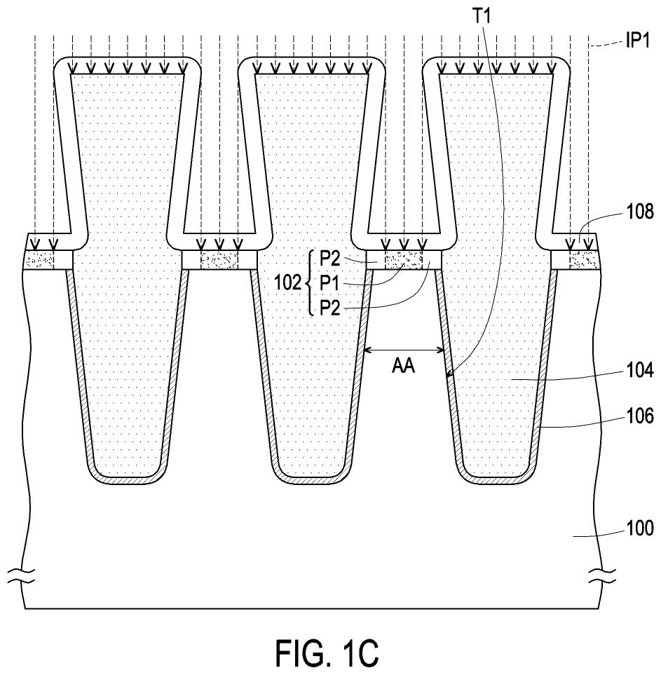

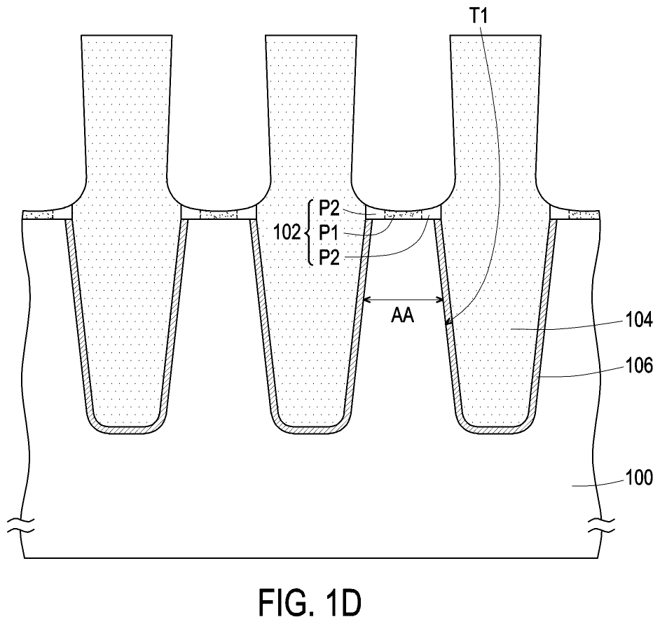

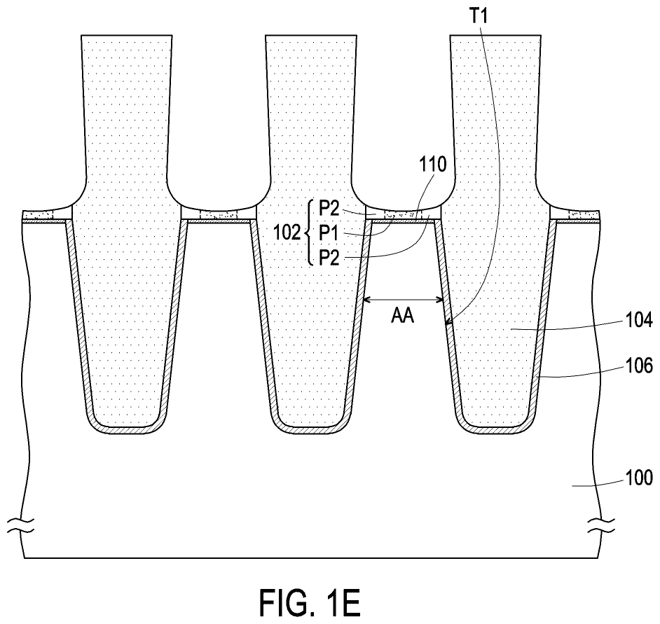

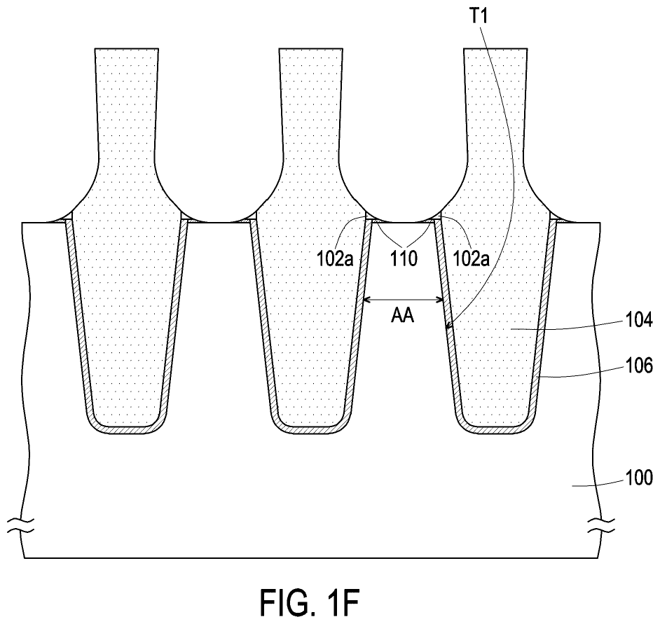

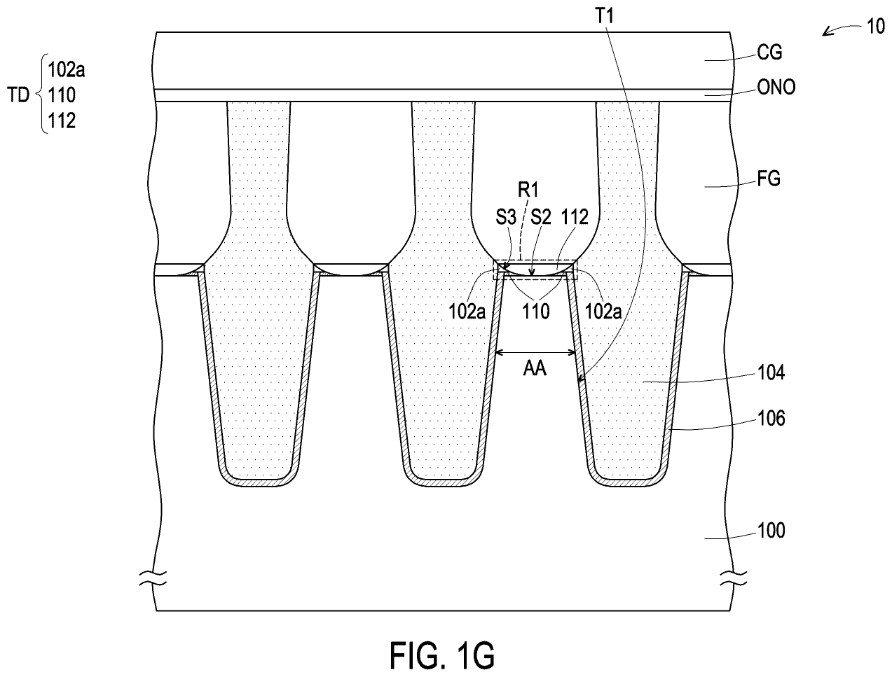

With reference to FIG. 1A, a substrate 100 is provided. The substrate 100 may be a semiconductor substrate, such as silicon, gallium arsenide, gallium nitride, germanium silicide, silicon on insulator (SOI), other suitable semiconductor materials, or a combination of the foregoing. In some embodiments, other structures may also be formed in the substrate 100, for example, a doped region (not shown). In the embodiments of the disclosure, the substrate 100 is a silicon substrate. Next, a pad oxide layer 102 is formed on the substrate 100. A material of the pad oxide layer 102 is, for example, silicon oxide. The pad oxide layer 102 is formed by, for example, thermal oxidation.

Next, a plurality of isolation structures 104 are formed in the pad oxide layer 102 and the substrate 100. The plurality of isolation structures 104 protrude from a top surface S1 of the pad oxide layer 102. The plurality of isolation structures 104 may define an active area AA in the substrate 100. The isolation structures 104 may be shallow trench isolation (STI) structures. A material of the isolation structures 104 is, for example, oxide (e.g., silicon oxide).

In some embodiments, the method of forming the plurality of isolation structures 104 may include the following steps. First, a pad nitride layer (not shown) may be formed on the pad oxide layer 102. Next, the pad nitride layer, the pad oxide layer 102, and the substrate 100 may be patterned to form a plurality of trenches T1 in the pad nitride layer, the pad oxide layer 102, and the substrate 100. After that, an isolation structure material layer (not shown) filling the plurality of trenches T1 may be formed. Next, the isolation structure material layer outside the plurality of trenches T1 is removed, and the plurality of isolation structures 104 are formed in the plurality of trenches T1. Subsequently, the pad nitride layer may be removed.

In some embodiments, before the isolation structure material layer is formed, a plurality of liner layers 106 may be formed on the substrate 100 exposed by the plurality of trenches T1. A material of the plurality of liner layers 106 is, for example, oxide (e.g., silicon oxide). The plurality of liner layers 106 may be formed by, for example, an in-situ steam generation (ISSG) method. Through the above method, the plurality of liner layers 106 may be formed between the plurality of isolation structures 104 and the substrate 100.

With reference to FIG. 1B, according to the embodiments of the disclosure, an ion implantation buffer layer 108 is formed on the plurality of isolation structures 104 and the pad oxide layer 102, so that a width W1 of a top portion of a recess 108R defined by a surface of the ion implantation buffer layer 108 is less than a width W2 of the pad oxide layer 102 between two adjacent isolation structures 104. In other words, two ends of the pad oxide layer 102 do not overlap with a vertical projection of the top portion of the recess 108R. In this embodiment, the ion implantation buffer layer 108 may be an oxide, such as silicon oxide, but the disclosure is not limited thereto. In this embodiment, a width of a top surface of each isolation structure 104 is greater than a width of a neck portion of the isolation structure 104, and the neck portion of the isolation structure 104 is at a level flush with the top surface of the pad oxide layer 102. Therefore, the ion implantation buffer layer 108 may be conformally formed on the isolation structures 104 and the pad oxide layer 102, so that the width W1 of the top portion of the recess 108R is less than the width W2 of the pad oxide layer 102. The ion implantation buffer layer 108 may be formed by atomic layer deposition.

With reference to FIG. 1C, according to the embodiments of the disclosure, after the ion implantation buffer layer 108 is formed, an ion implantation process IP1 is performed on the ion implantation buffer layer 108 and the pad oxide layer 102, so that the pad oxide layer 102 between two adjacent isolation structures 104 includes multiple portions with different doping levels, such as a doped portion P1 (i.e., a central portion) and an undoped portion P2 (i.e., two side portions). The ion implantation buffer layer 108 located on the sidewalls of the isolation structures 104 has a greater vertical thickness, so that implantation of dopants into both ends of the pad oxide layer 102 may be prevented or lowered. Therefore, two undoped portions P2 or low-doped portions may be formed at both ends of the pad oxide layer 102. That is, the doping level of the central portion of the pad oxide layer 102 may be greater than the doping level of the two side portions of the pad oxide layer 102. The undoped portions P2 may be located directly below the ion implantation buffer layer 108 on the sidewalls of the isolation structures 104 and may not overlap with the vertical projection of the top portion of the recess 108R. The doped portion P1 may overlap with the vertical projection of the top portion of the recess 108R. The two undoped portions P2 are located on both sides of the doped portion P1. In other words, the undoped portions P2 are located between the doped portion P1 and the corresponding isolation structure 104. In this embodiment, by performing the ion implantation process IP1, the portion (i.e., the central portion) with a higher doping level of the pad oxide layer 102 may be removed more easily in subsequent processes than the portions (i.e., the side portions) with a lower doping level. In some embodiments, a dopant used in the ion implantation process IP1 may include a P-type dopant, such as boron difluoride (BF2) or boron.

With reference to FIG. 1D, a first etching process may be performed to remove the ion implantation buffer layer 108 and partially remove the doped pad oxide layer 102 (including the doped portion P1 (i.e., the central portion) and the undoped portions P2 (i.e., the side portions)). In the first etching process, an etching rate of the doped portion P1 (i.e., the central portion of the pad oxide layer 102) may be greater than an etching rate of the undoped portions P2 (i.e., the two side portions of the pad oxide layer 102). In some embodiments, the isolation structures 104 may be partially removed during the first etching process. In a preferred embodiment, the first etching process may be wet etching to reduce carbon emission and avoid damaging the substrate 100.

With reference to FIG. 1E, an in-situ steam generation process may be optionally performed to form a substrate surface repair layer 110 between the pad oxide layer 102 and the substrate 100. In this way, a surface of the substrate 100 in the active area AA may be repaired. A material of the substrate surface repair layer 110 may include oxide, such as silicon oxide.

With reference to FIG. 1F, a second wet etching process may be performed to completely remove the doped portion P1 (i.e., the central portion) of the doped pad oxide layer 102 and partially remove the undoped portions P2 (i.e., the two side portions) of the doped pad oxide layer 102 and the substrate surface repair layer 110, to form two corner oxide layers 102a at two corners between two adjacent isolation structures 104, and to expose a portion of the substrate 100. A material of the corner oxide layer 102a is, for example, silicon oxide. In the second etching process, the etching rate of the doped portion P1 (i.e., the central portion of the pad oxide layer 102) may be greater than the etching rate of the undoped portions P2 (i.e., the two side portions of the pad oxide layer 102). After the second etching process is performed, a portion of the substrate surface repair layer 110 is located between the two corner oxide layers 102a and the substrate 100. In some embodiments, the isolation structures 104 may be partially removed during the second etching process. In a preferred embodiment, the second etching process may be wet etching to reduce carbon emission of the process and avoid damaging the substrate 100.

In the above embodiments, the ion implantation buffer layer 108 and the doped pad oxide layer 102 (including the doped portion P1 and the plurality of undoped portions P2) may be subjected to two etching processes (preferably wet etching) by the above method to form the plurality of corner oxide layers 102a at the corners between two adjacent isolation structures 104 and to expose a portion of the substrate 100. However, in some other embodiments, only a single etching process may be performed to form the plurality of corner oxide layers 102a.

In some other embodiments, the in-situ steam generation process for forming the substrate surface repair layer 110 may be omitted. In the etching process of the above embodiments, since the doped portion P1 of the pad oxide layer 102 has a faster etching rate, the doped portion P1 located in a central region of the pad oxide layer 102 may be effectively removed.

With reference to FIG. 1G, an oxide layer 112 may be formed on the substrate 100, such that the corner oxide layers 102a are located between the oxide layer 112 and the substrate 100. In some embodiments, the oxide layer 112 and the corner oxide layers 102a may be collectively referred to as a tunneling dielectric layer TD of a flash memory. That is, the tunneling dielectric layer TD may include the oxide layer 112 and the corner oxide layers 102a. In addition, the tunneling dielectric layer TD may further include the substrate surface repair layer 110. According to this embodiment, a thickness of the tunneling dielectric layer TD located at a corner of the active area AA may be effectively increased. In this way, data retention capability and reliability of the flash memory formed subsequently may be effectively improved. A material of the oxide layer 112 is, for example, silicon oxide. The oxide layer 112 is formed by, for example, thermal oxidation. Next, a floating gate FG, an inter-gate dielectric layer ONO (e.g., including an oxide layer-nitride layer-oxide layer), and a control gate CG may be sequentially formed on the tunneling dielectric layer TD. Materials of the floating gate FG and the control gate CG may include doped polysilicon. After the control gate CG is formed, other known processes may be performed according to actual needs to complete a flash memory 10. As for other known processes, description thereof is not repeated herein.

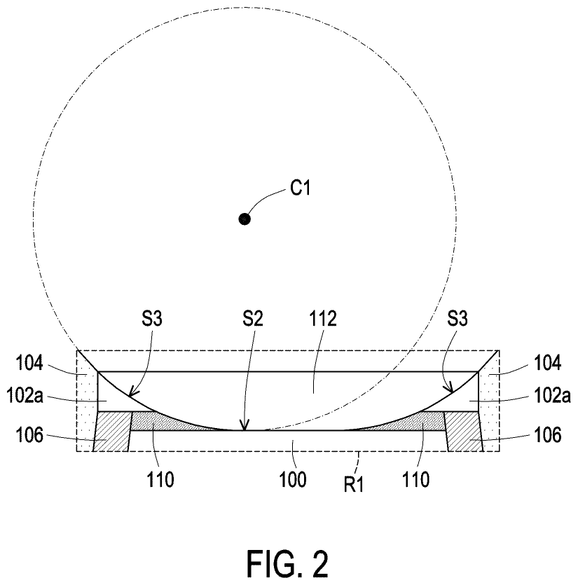

FIG. 1G and FIG. 2 are used to illustrate the flash memory 10 in an embodiment of the disclosure. The method for forming the flash memory 10 may refer to the above description, but the disclosure is not limited thereto. The flash memory 10 includes the substrate 100, the plurality of isolation structures 104, the plurality of corner oxide layers 102a, and the oxide layer 112. The plurality of isolation structures 104 are located in the substrate 100 and protrude from a top surface S2 of the substrate 100. The corner oxide layers 102a are located on the substrate 100 at the corners between two adjacent isolation structures 104. A center of curvature Cl of an upper surface S3 of each corner oxide layer 102a is located on a side of the upper surface S3 away from the substrate 100. The upper surface S3 of each corner oxide layer 102a may include a concave surface. An oxide layer 112 is located on the substrate 100 between two adjacent isolation structures 104. The corner oxide layers 102a are located between the oxide layer 112 and the substrate 100. The oxide layer 112 may cover the upper surface S3 of each of the corner oxide layers 102a. The flash memory 10 may further include the plurality of liner layers 106. The liner layers 106 are located between the isolation structures 104 and the substrate 100. The flash memory 10 may further include the floating gate FG, the inter-gate dielectric layer ONO, and the control gate CG sequentially disposed on the oxide layer 112. The flash memory 10 may further include the substrate surface repair layer 110 located between the corner oxide layers 102a and the substrate 100.

In addition, the details (for example, materials and formation methods, etc.) of each component in the flash memory 10 are described in detail in the above embodiments and thus are not described again herein.

Based on the above, in the flash memory 10 and the manufacturing method, since the corner oxide layers 102a between the adjacent isolation structures 104 are located between the oxide layer 112 and the substrate 100, corner thinning in the tunneling dielectric layer TD on the active area is prevented. In this way, the electrical performance (e.g., data retention capability) and reliability of the flash memory formed subsequently may be effectively improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a flash memory, comprising:
forming a plurality of isolation structures in a substrate and protruding from a top surface of the substrate; and
forming a tunneling dielectric layer comprising:
a plurality of corner oxide layers located on the substrate at a plurality of corners between two adjacent isolation structures, wherein a center of curvature of an upper surface of each of the corner oxide layers is located on a side of the upper surface away from the substrate; and
an oxide layer located on the substrate between two adjacent isolation structures, wherein the plurality of corner oxide layers are located between the oxide layer and the substrate.

2. The manufacturing method of the flash memory according to claim 1, further comprising:
forming a pad oxide layer on the substrate, wherein the plurality of isolation structures protrude from a top surface of the pad oxide layer;
forming an ion implantation buffer layer on the plurality of isolation structures and the pad oxide layer, so that a width of a top portion of a recess defined by a surface of the ion implantation buffer layer is less than a width of the pad oxide layer between two adjacent isolation structures;
performing an ion implantation process on the ion implantation buffer layer and the pad oxide layer, so that doping levels of a central portion and two side portions of the pad oxide layer between two adjacent isolation structures are different;
performing an etching process on the ion implantation buffer layer and the doped pad oxide layer to form the plurality of corner oxide layers and to expose a portion of the substrate, wherein in the etching process, an etching rate of the central portion of the pad oxide layer is greater than an etching rate of the two side portions of the pad oxide layer; and
forming the oxide layer on the exposed portion of the substrate and the plurality of corner oxide layers.

3. The manufacturing method of the flash memory according to claim 1, wherein the upper surface of the corner oxide layer is lower than a top surface of the isolation structure.

4. The manufacturing method of the flash memory according to claim 2, wherein the ion implantation buffer layer is conformally formed on the plurality of isolation structures and the pad oxide layer, and the etching process comprises wet etching.

5. The manufacturing method of the flash memory according to claim 2, wherein a width of a top surface of each isolation structure is greater than a width of a neck portion of the isolation structure, and the neck portion of the isolation structure is at a level flush with the top surface of the pad oxide layer.

6. The manufacturing method of the flash memory according to claim 2, further comprising sequentially forming a floating gate, an inter-gate dielectric layer, and a control gate on the tunneling dielectric layer, wherein a dopant used in the ion implantation process comprises a P-type dopant.

7. The manufacturing method of the flash memory according to claim 6, wherein a center of a bottom surface of the floating gate is not lower than an edge of the bottom surface.

8. The manufacturing method of the flash memory according to claim 2, wherein a dopant used in the ion implantation process comprises boron difluoride or boron.

9. The manufacturing method of the flash memory according to claim 2, wherein the doping level of the central portion of the pad oxide layer is greater than the doping level of the two side portions of the pad oxide layer.

10. The manufacturing method of the flash memory according to claim 2, wherein the etching process comprises:
performing a first wet etching process to remove the ion implantation buffer layer and partially remove the doped pad oxide layer;
performing an in-situ steam generation process to form a substrate surface repair layer between the pad oxide layer and the substrate; and
performing a second wet etching process to completely remove the central portion of the doped pad oxide layer and partially remove the two side portions of the doped pad oxide layer and the substrate surface repair layer, so as to form the plurality of corner oxide layers at the plurality of corners between two adjacent isolation structures and to expose a portion of the substrate,
wherein the tunneling dielectric layer comprises the oxide layer, the corner oxide layers, and the substrate surface repair layer.

11. The manufacturing method of the flash memory according to claim 8, wherein the doping level of the central portion of the pad oxide layer is greater than the doping level of the two side portions of the pad oxide layer, and a material of the substrate surface repair layer comprises oxide.

12. The manufacturing method of the flash memory according to claim 1, wherein a center of curvature of an upper surface of each of the corner oxide layers is located on a side of the upper surface away from the substrate.

13. A flash memory, comprising:
a substrate;
a plurality of isolation structures in the substrate and protruding from a top surface of the substrate; and
a tunneling dielectric layer comprising:
a plurality of corner oxide layers located on the substrate at a plurality of corners between two adjacent isolation structures, wherein a center of curvature of an upper surface of each of the corner oxide layers is located on a side of the upper surface away from the substrate; and
an oxide layer located on the substrate between two adjacent isolation structures, wherein the plurality of corner oxide layers are located between the oxide layer and the substrate.

14. The flash memory according to claim 13, wherein the upper surface of the corner oxide layer is lower than the top surface of the isolation structure.

15. The flash memory according to claim 13, further comprising a floating gate, an inter-gate dielectric layer, and a control gate sequentially disposed on the oxide layer, the upper surface of each of the corner oxide layers comprises a concave surface.

16. The flash memory according to claim 15, wherein a center thickness of the floating gate is not greater than an edge thickness of the floating gate.

17. The flash memory according to claim 15, wherein a center of a bottom surface of the floating gate is not lower than an edge of the bottom surface.

18. The flash memory according to claim 13, wherein the oxide layer covers the upper surfaces of the plurality of the corner oxide layers.

19. The flash memory according to claim 13, further comprising:
a substrate surface repair layer located between each of the corner oxide layers and the substrate.

20. The flash memory according to claim 19, wherein a material of the substrate surface repair layer comprises oxide.
